(19) United States
(12) Patent Application Publication
(10) Pub. No.: US 2017/0094836 A1
(43) Pub. Date: Mar. 30, 2017

(54) DOUBLE-SIDED HEAT EXCHANGER FOR FLUID-COOLED ELECTRONICS WITH A FLAT COPLANAR SERIES-WISE COOLANT FLOW PATH

(71) Applicant: DELPHI TECHNOLOGIES, INC., TROY, MI (US)

(72) Inventors: Brian Lo, San Francisco, CA (US); Mark A. Ebenhart, Kokomo, IN (US)

(21) Appl. No.: 15/228,008

(22) Filed: Aug. 4, 2016

Related U.S. Application Data
(60) Provisional application No. 62/234,746, filed on Sep. 30, 2015.

(51) Int. Cl. H05K 7/20; H01L 23/473

(52) U.S. Cl. CPC H05K 7/20272; H01L 23/473

(57) ABSTRACT

A fluid-cooled electronics assembly for high-power electronics includes an arrangement of electronic components that defines an upper-side of the arrangement and a lower-side of the arrangement opposite the upper-side. An upper-chamber is thermally coupled to the upper-side, and a lower-chamber thermally coupled to the lower-side. The upper-chamber and the lower-chamber are further configured to direct flowing-coolant series-wise from the lower-chamber into the upper-chamber. The upper-chamber and the lower-chamber are further configured to cooperatively define a manifold-connection operable to couple the assembly to a manifold-outlet and a manifold-inlet of a coolant-manifold. The assembly also includes a fitting configured to define an inlet-port of the assembly that directs the flowing-coolant from the manifold-outlet to the lower-inlet, and an outlet-port that directs the flowing-coolant from the upper-outlet to the manifold-inlet. The inlet-port and the outlet-port are characterized as adjacent and side-by-side ports that are segregated from each other by a wall-section.

### TECHNICAL FIELD OF INVENTION

This disclosure generally relates to a fluid-cooled electronics assembly configured to provide a flat coplanar series-wise coolant flow path.

### BACKGROUND OF INVENTION

It is known that high-power electronic devices such as solid-state power switches need to have heat removed for reliable operation. In electric-vehicle applications the ambient temperature may require circulated liquid coolant to remove enough heat to maintain reliability. Automotive applications are highly cost sensitive and high packaging density is desired, so the configuration of the electronics packaging and coolant management is critical.

### SUMMARY OF THE INVENTION

Described herein is a flat-coplanar-heat-exchanger suitable for use in an electric-vehicle that provides for double-sided series-wise of fluid coolant to remove heat from both sides of electrical components.

In accordance with one embodiment, a fluid-cooled electronics assembly for high-power electronics is provided. The assembly includes an arrangement of electronic components that defines an upper-side of the arrangement, and a lower-side of the arrangement opposite the upper-side. An upper-chamber is thermally coupled to the upper-side. The upper-chamber is configured to guide flowing-coolant from an upper-inlet to an upper-outlet to remove heat from the upper-side. A lower-chamber is thermally coupled to the lower-side. The lower-chamber is configured to guide flowing-coolant from a lower-inlet to a lower-outlet to remove heat from the lower-side. The upper-chamber and the lower-chamber are further configured to cooperatively define a transfer-path that fluidicly couples the lower-outlet to the upper-inlet such that the flowing-coolant flows series-wise from the lower-chamber into the upper-chamber. The upper-chamber and the lower-chamber are further configured to cooperatively define a manifold-connection operable to couple the assembly to a manifold-outlet and a manifold-inlet of a coolant-manifold such that the flowing-coolant flows through the assembly. The assembly also includes a fitting configured to define an inlet-port of the assembly that directs the flowing-coolant from the manifold-outlet to the lower-inlet, and an outlet-port that directs the flowing-coolant from the upper-outlet to the manifold-inlet. The inlet-port and the outlet-port are characterized as adjacent and side-by-side ports that are segregated from each other by a wall-section.

Further features and advantages will appear more clearly on a reading of the following detailed description of the preferred embodiment, which is given by way of non-limiting example only and with reference to the accompanying drawings.

### BRIEF DESCRIPTION OF DRAWINGS

The present invention will now be described, by way of example with reference to the accompanying drawings, in which:

FIG. 1 is a fluid cooled electronics assembly in accordance with one embodiment;

FIG. 2 is a sectional view of the assembly of FIG. 1 in accordance with one embodiment;

FIG. 3 is an exploded view of the assembly of FIG. 1 in accordance with one embodiment;

FIG. 4 is a fitting used in the assembly of FIG. 1 in accordance with one embodiment; and

FIG. 5 is an alternative fluid cooled electronics assembly with an alternative fitting in accordance with one embodiment.

### DETAILED DESCRIPTION

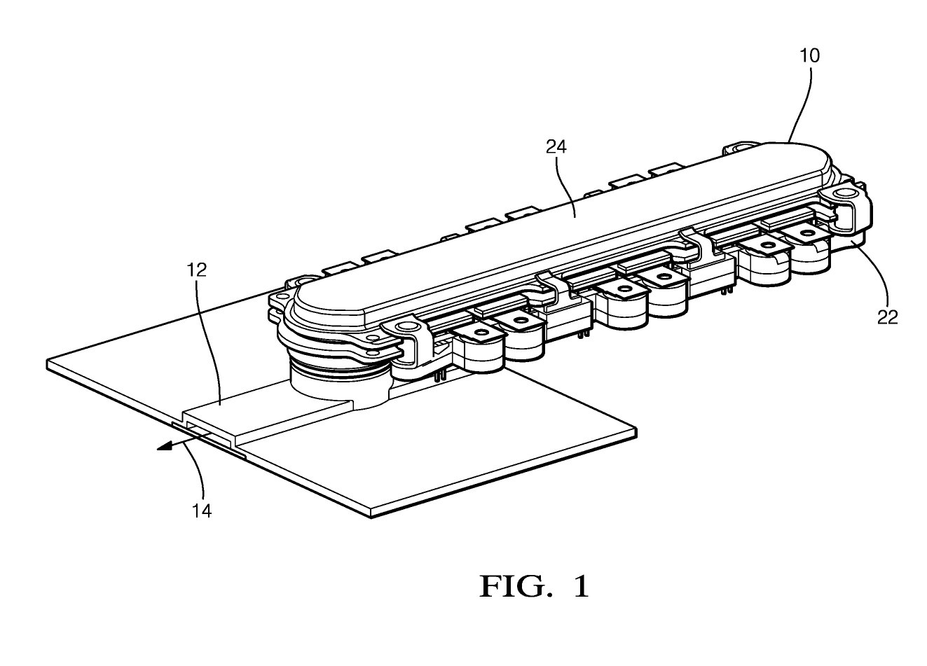

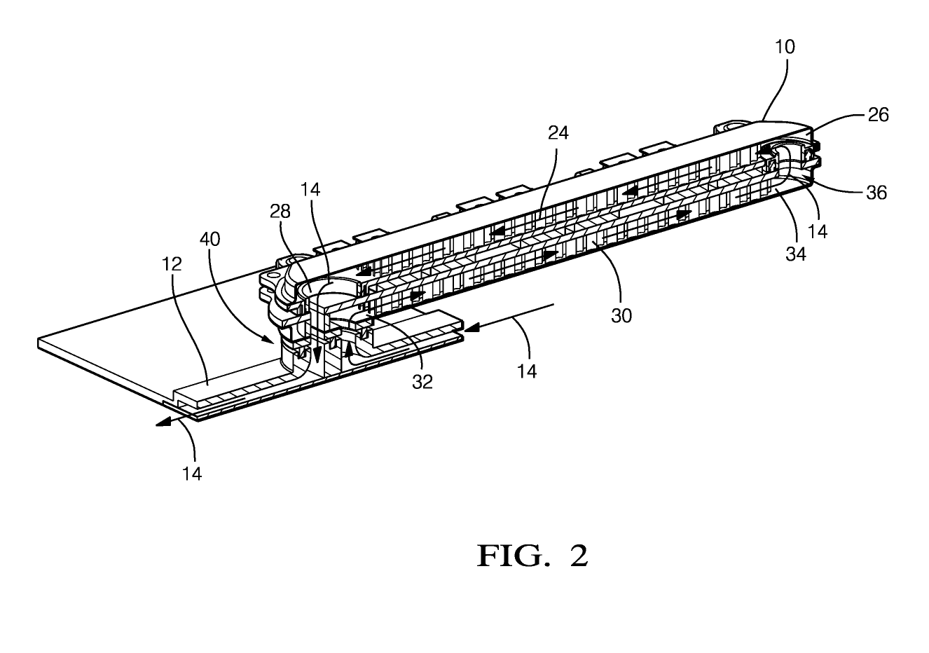

FIGS. 1 and 2 illustrate a non-limiting example of a fluid-cooled electronics assembly, hereafter referred to as the assembly 10. In general, the assembly 10 is particularly useful for cooling high-power electronics such as an inverter used to control the flow of electrical energy from a bank of batteries (not shown) to an electric-motor used to propel an electric-vehicle (not shown). The assembly 10 is fluidicly coupled to a coolant-manifold 12 in a manner effective so flowing-coolant 14 can be directed through the assembly 10, the details of which are explained later.

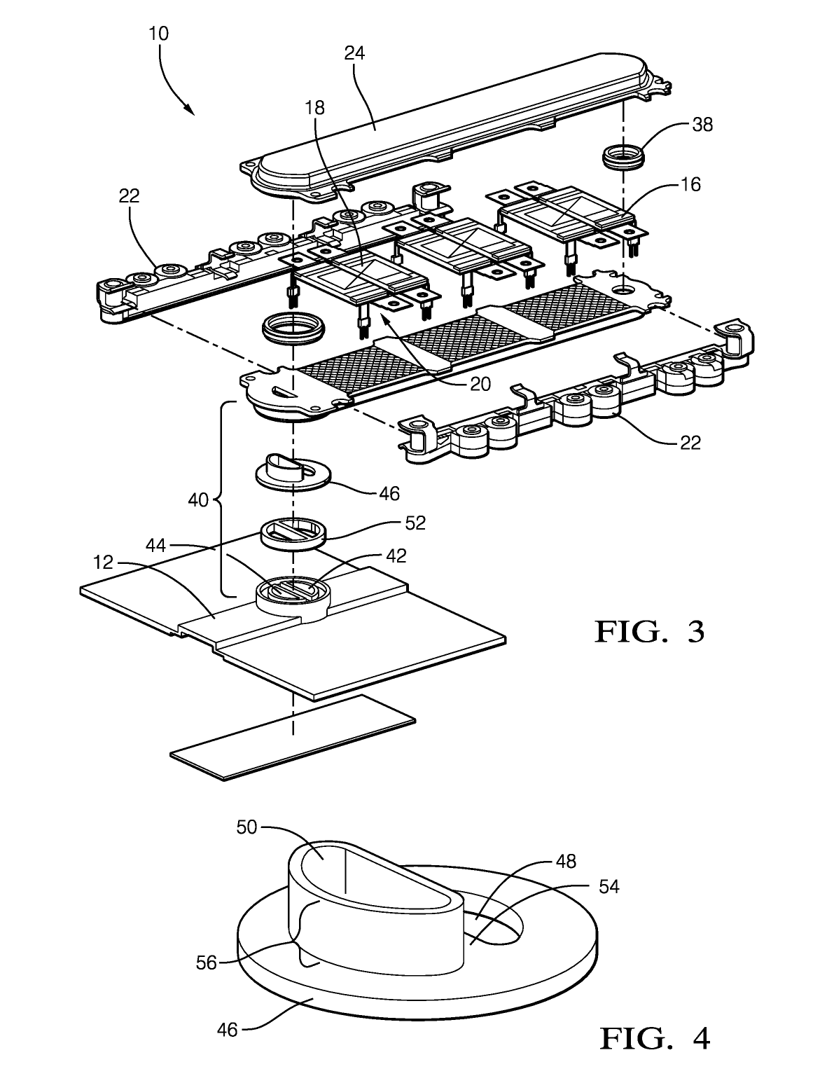

FIG. 3 further illustrates details of the assembly 10 which includes an arrangement 16 of electronic components that defines an upper-side 18 of the arrangement 16 and a lower-side 20 of the arrangement 16 opposite the upper-side 18. That is, the electronic components that form the arrangement 16 are configured so heat can be removed from both opposing sides of the electronic components. It is contemplated that electrical connections to the electronic components may be made on the surfaces of the electronic components that define the upper-side 18 and/or the lower-side 20, and that other electrical connections may be made at the perimeters of the electronic components by, for example, electrical-contacts 22.

To provide double-sided cooling for the electronic components, the assembly 10 includes an upper-chamber 24 (i.e. upper heat-sink) thermally coupled to the upper-side 18, and a lower-chamber 30 (i.e. lower heat-sink) thermally coupled to the lower-side 20. The upper-chamber 24 is configured to guide the flowing-coolant 14 from an upper-inlet 26 to an upper-outlet 28 to remove heat from the upper-side 18. Similarly, the lower-chamber 30 is configured to guide flowing-coolant from a lower-inlet 32 to a lower-outlet 34 to remove heat from the lower-side 20. The upper-chamber 24 and the lower-chamber 30 may be formed of a polymeric compound, or may be formed from sheet-metal that is stamped, formed, and friction-welded to form the respective chambers.

As used herein, the use of relative terms such as ‘upper’ and ‘lower’, and the designations of particular features as ‘inlet’ and ‘outlet’ are only for the purpose of simplifying the explanation of the assembly 10, and not to be construed as any particular limitation. For example, it is contemplated that the direction of the flowing-coolant 14 could be reversed so that the flowing-coolant passes through the upper-chamber 24 before passing through the lower-chamber 30, which may result in exchanging each instance of the terms ‘inlet’ and ‘outlet’.

The upper-chamber 24 and the lower-chamber 30 are advantageously configured to cooperatively define a transfer-path 36 that fluidicly couples the lower-outlet 34 to the upper-inlet 26 such that the flowing-coolant 14 flows series-wise from the lower-chamber 30 into the upper-chamber 24. As used herein, the term ‘series-wise’ means that the same sampling of the flowing-coolant 14 that flows through the lower-chamber 30 will eventually flow through the upper-chamber 24, and that the volume flow-rate of the flowing-coolant 14 that flows through the lower-chamber 30 equals the volume flow-rate of the flowing-coolant 14 that flows through the upper-chamber 24. It is noted that the flowing-coolant 14 in the lower-chamber 30 flows in a direction that is generally characterized as parallel to, but in the opposite direction of the flowing-coolant 14 in the upper-chamber 24. The assembly may include a transfer-seal 38 configured to seal the transfer-path 36. The transfer-seal 38 may be formed of, for example, a silicon-rubber compound.

The upper-chamber 24 and the lower-chamber 30 are further advantageously configured to cooperatively define a manifold-connection 40 operable to couple the assembly 10 to a manifold-outlet 42 and a manifold-inlet 44 of the coolant-manifold 12 such that the flowing-coolant 14 flows through the assembly 10. The assembly 10, or more specifically the manifold-connection 40, includes a fitting 46, and may include a fitting-seal 52 formed of the same material used to form the transfer-seal 38.

FIG. 4 illustrates some non-limiting details of one embodiment of the fitting 46. The fitting 46 is generally configured to define an inlet-port 48 of the assembly 10 that directs the flowing-coolant 14 from the manifold-outlet 42 to the lower-inlet 32, and an outlet-port 50 that directs the flowing-coolant 14 from the upper-outlet 28 to the manifold-inlet 44. The inlet-port 48 and the outlet-port 50 are characterized as adjacent and side-by-side ports that are segregated from each other by a wall-section 54. That is, the flowing-coolant 14 in the inlet-port 48 is beside the flowing-coolant 14 in the outlet-port 50. More specifically, the inlet-port 48 and the outlet-port 50 do not have a coaxial relationship. A coaxial design was contemplated where the inlet and the outlet to the manifold consisted of a central circular opening and surrounded by a ring-shaped. The central opening allows fluid to bypass the bottom heat sink and flow directly to the top heat sink. However, these coaxial openings resulted in an undesirable packaging height. The problem associated with the height of the coaxial design combined with the desire for fluid to flow on two different planes was solved by the side-by-side configuration of the manifold-connection described herein.

In the embodiment of the fitting 46 shown in FIG. 4, the fitting 46 is further configured to define an extended-portion 56 that further defines the outlet-port 50 between the upper-chamber 24 and the coolant-manifold 12 that passes through a portion of the lower-chamber 30.

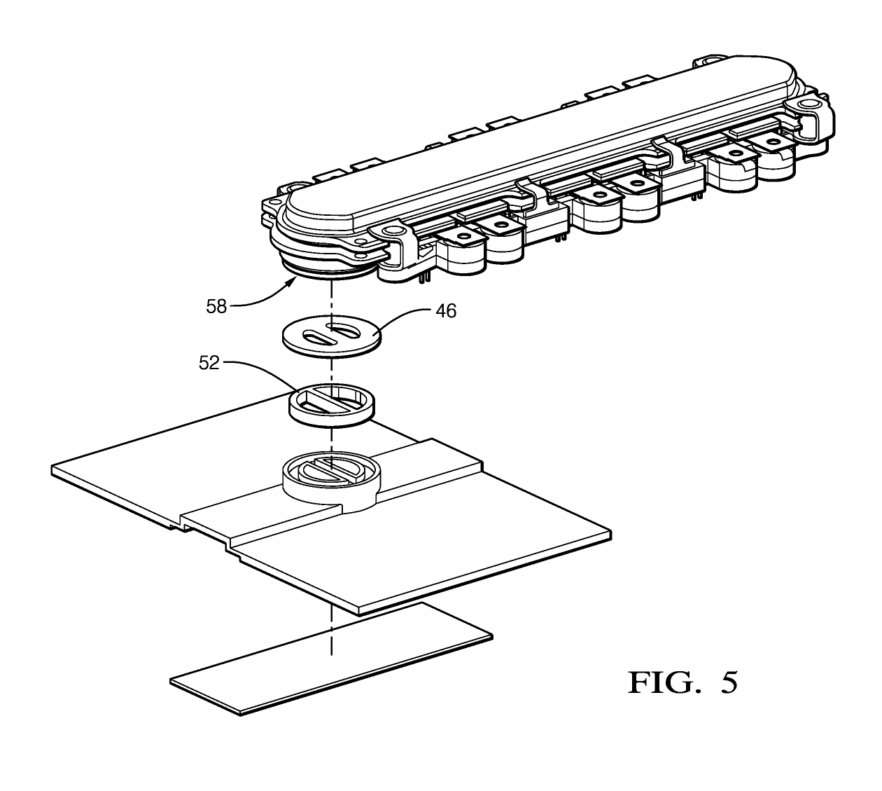

FIG. 5 shows an alternative embodiment of the fitting 46 that does not include the extended-portion 56. In this example, the lower-chamber 30 is further configured to define a via-portion 58. While the via-portion 58 is not specifically shown, it is understood to have a shape similar to the extended-portion 56 and cooperates with the flat embodiment of the fitting 46 shown in FIG. 5 to define a pathway similar to the outlet-port 50 between the upper-chamber 24 and the coolant-manifold 12 though the body of the lower-chamber 30.

Accordingly, a fluid-cooled electronics assembly for high-power electronics (the assembly 10) is provided. The problems with the coaxial design are solved through the use of a flat coplanar spout fitting. The new design features a novel flat interface with two openings or ports in a side-by-side configuration, one of which bypasses the lower-chamber 30. These two openings are separated to allow for a seal or gasket, and friction-stir weld-path to be placed between the two openings, thereby eliminating the need for a tall spout and complex coolant-manifold. This design elegantly separates the inlet and outlet fluid in a simple low profile fitting. The coplanar design differs from the coaxial design in that all the openings are on one plane and that the inlet and outlet ports are not concentric. The advantages of these changes are the low profile fitting and a simple inlet and outlet design.

While this invention has been described in terms of the preferred embodiments thereof, it is not intended to be so limited, but rather only to the extent set forth in the claims that follow.

We claim:

1. A fluid-cooled electronics assembly for high-power electronics, said assembly comprising:
an arrangement of electronic components that defines an upper-side of the arrangement and a lower-side of the arrangement opposite the upper-side;
an upper-chamber thermally coupled to the upper-side, said upper-chamber configured to guide flowing-coolant from an upper-inlet to an upper-outlet to remove heat from the upper-side;
a lower-chamber thermally coupled to the lower-side, said lower-chamber configured to guide flowing-coolant from a lower-inlet to a lower-outlet to remove heat from the lower-side,
wherein the upper-chamber and the lower-chamber are further configured to cooperatively define a transfer-path that fluidicly couples the lower-outlet to the upper-inlet such that the flowing-coolant flows series-wise from the lower-chamber into the upper-chamber,
wherein the upper-chamber and the lower-chamber are further configured to cooperatively define a manifold-connection operable to couple the assembly to a manifold-outlet and a manifold-inlet of a coolant-manifold such that the flowing-coolant flows through the assembly; and
a fitting configured to define an inlet-port of the assembly that directs the flowing-coolant from the manifold-outlet to the lower-inlet, and an outlet-port that directs the flowing-coolant from the upper-outlet to the manifold-inlet, wherein the inlet-port and the outlet-port are characterized as adjacent and side-by-side ports that are segregated from each other by a wall-section.

2. The assembly in accordance with claim 1, wherein the fitting is further configured to define an extended-portion that defines the outlet-port between the upper-chamber and the coolant-manifold though the lower-chamber.

3. The assembly in accordance with claim 1, wherein the lower-chamber is further configured to define a via-portion that defines the outlet-port between the upper-chamber and the coolant-manifold though the lower-chamber.
